(19) United States
(12) Patent Application Publication
(10) Pub. No.: US 2026/0184988 A1
(43) Pub. Date: Jul. 2, 2026

(54) QUANTUM DOTS, METHOD FOR MANUFACTURING SAME, AND ELECTRONIC DEVICE

(71) Applicant: DUK SAN NEOLUX CO., LTD., Cheonan-si, Chungcheongnam-do (KR)

(72) Inventors: Han Byule LIM, Cheonan-si (KR); Chang Min LEE, Cheonan-si (KR); Jong Moon SHIN, Cheonan-si (KR); Kyung Soo KIM, Cheonan-si (KR)

(21) Appl. No.: 19/129,052

(22) PCT Filed: Oct. 20, 2023
(86) PCT No.: PCT/KR2023/016339

§ 371 Date: May 12, 2025

(30) Foreign Application Priority Data
Nov. 17, 2022 (KR) 10-2022-0154930

(51) Int. Cl. C09K 11/62; C09K 113/00; H10H 20/812; H10H 20/851; H10K 50/115

(52) U.S. Cl. CPC C09K 11/621; H10H 20/812; H10H 20/8512; H10K 50/115; C09K 2113/00

(57) ABSTRACT

The present embodiments may provide quantum dots having effective absorption efficiency of 50% or greater, a method for manufacturing same, and an electronic device, each quantum dots comprising a core comprising Ag, In, Ga, and S, and a shell disposed on the core.

### TECHNICAL FIELD

The present disclosure relates to a quantum dot, a method of manufacturing the quantum dot, and an electronic device.

### BACKGROUND ART

Quantum dots (QDs) are semiconductor particles having a size of a few nanometers and having superior optical and electric properties that differ from bulk semiconductor materials. For example, quantum dots have characteristics of emitting light through photoluminescence (PL), in which light is generated as electrons drop down from the conduction band to the valence band, or electroluminescence (EL), in which light is generated by external charges. Even in the case in which the quantum dots are formed of the same material, the color of emission light may vary depending on the size of the quantum dots. Due to these characteristics, quantum dots are attracting attention for use in next-generation light-emitting diodes (LEDs), biosensors, lasers, solar cell nanomaterials, and the like.

Meanwhile, the core surface of the quantum dot easily forms chemical bonds when approached by other atoms or molecules, which may cause surface defects and reduce luminescence efficiency. Accordingly, in order to prevent a decrease in luminescence efficiency of the core, the quantum dot with core/shell structure in which the shell is formed on the core surface has been developed.

However, despite the introduction of the shell, there is a problem in that the luminescence efficiency of quantum dots is limited to a certain level.

### DISCLOSURE

### Technical Problem

Embodiments of the present disclosure may provide a quantum dot with improved luminescence efficiency, a method of manufacturing the quantum dot, and an electronic device.

### Technical Solution

In an aspect, embodiments of the present disclosure may provide a quantum dot comprising a core including silver (Ag), indium (In), gallium (Ga) and sulfur(S), and a shell on the core, wherein the quantum dot may have an effective absorption efficiency defined by [Equation 1] of greater than or equal to 50%.

$$effective absorption efficiency ( \% ) = \frac{{Abs}_{300 nm ∼ 470 nm} \times {( QY )}^{2}}{10000} \times 100 \qquad [ Equation 1 ]$$

Wherein Equation 1, Abs_{300 nm˜470 nm} may be an integral value of an absorbance of a quantum dot in the range of 300 nm to 470 nm when an integral value of an absorbance of a quantum dot in the range of 300 nm to 800 nm is 1, and QY may be a quantum yield of a quantum dot.

A quantum yield of the quantum dot may be greater than or equal to 70% when an effective absorption efficiency of a quantum dot may be greater than or equal to 50%.

A shell may include at least one of a Group I element and a Group III element; and a Group VI element.

A Group I element included in the shell may include one or more selected from Li, Na, K, Rb, Cs, Cu, Ag, and Au.

A Group III element included in the shell may include one or more selected from Au. Al, Ga, In and Tl.

A Group VI element included in the shell may include one or more selected from S, Se and Te.

A shell may include a first shell and a second shell. A first shell may be disposed on the core and may include a Group I element and a Group III element, and a Group VI element. A second shell may be disposed on the first shell and may include a Group III element and a Group VI element. The Group III element and the Group VI element included in the first shell and the second shell may be the same or different.

A first shell may include one of AgAlS, AgAlSe, AgAlTe, AgGaS, AgGaSe, AgGaTe, AgInS, AgInSe, AgInTe, AgTiS, AgTiSe, AgTiTe, CuAlS, CuAlSe, CuAlTe, CuGaS, CuGaSe, CuGaTe, CuInS, CuInSe, CuInTe, CuTiS, CuTiSe, CuTiTe, AuAlS, AuAlSe, AuAlTe, AuGaS, AuGaSe, AuGaTe, AuInS, AuInSe, AuInTe, AuTiS, AuTiSe, and AuTiTe.

A second shell may include one of AlS, AlSe, AlTe, GaS, GaSe, GaTe, InS, InSe, InTe, TiS, TiSe, and TiTe.

In another aspect, embodiments of the present disclosure may provide a method of manufacturing a quantum dot.

A method of manufacturing a quantum dot may comprise a core preparation step and a shell preparation step.

A core preparation step may be a step of preparing a core by injecting and reacting a silver precursor, an indium precursor, a gallium precursor, a sulfur precursor and a solvent in a first reactor.

A shell preparation step may be a step of preparing a shell by injecting and reacting the prepared core in a second reactor containing a precursor including specific elements.

A quantum dot may have an effective absorption efficiency defined by above [Equation 1] of greater than or equal to 50%.

A quantum yield of the quantum dot may be greater than or equal to 70% when an effective absorption efficiency of a quantum dot may be greater than or equal to 50%.

Specific elements may include at least one of a Group I element and a Group III element; and a Group VI element.

A core preparation step may comprise a step 1-1 and a step 1-2.

A step 1-1 may be a step of preparing a core solution by injecting and heating a silver precursor, an indium precursor, a gallium precursor, a sulfur precursor and a solvent in a first reactor.

A step 1-2 may be a step of adding a purification solvent to a core solution and centrifuging a resulting product, and dispersing a precipitate separated through centrifugation in a dispersion solvent.

A shell preparation step may comprise a step 2-1 and a step 2-2.

A step 2-1 may be a step of injecting at least one of a Group I precursor and a Group III precursor in a second reactor containing an oleyamine.

A step 2-2 may be a step of injecting and reacting a purified core and a Group VI precursor including a Group VI element in a second reactor.

A shell may include a first shell and a second shell. A first shell may be disposed on the core and may include a Group I element and a Group III element, and a Group VI element.

A second shell may be disposed on the first shell and may include a Group III element and a Group VI element. The Group III element and the Group VI element included in the first shell and the second shell may be the same or different.

A shell preparation step may include a first shell preparation step and a second shell preparation step. A first shell preparation step may prepare a first shell by injecting and reacting the prepared core in the first reactor containing a Group I precursor including the Group I element and a Group III precursor including the Group III element, and a Group VI precursor including the Group VI element. A second shell preparation step may prepare a second shell by injecting and reacting the prepared core/first shell in the second reactor containing a Group III precursor including the Group III element and a Group VI precursor including the Group VI element.

In another aspect, embodiments of the present disclosure may provide an electronic device comprising a display device including a light emitting diode including a quantum dot, and a controller driving the display device. A quantum dot may comprise a core including silver (Ag), indium (In), gallium (Ga) and sulfur(S), and a shell on the core, wherein an effective absorption efficiency of a quantum dot defined by the above [Equation 1] may be greater than or equal to 50%.

### Advantageous Effects

In a quantum dot, method for manufacturing a quantum dot, and electronic device according to embodiments of the present disclosure, the luminescence efficiency of the quantum dot may be improved.

### DESCRIPTION OF DRAWINGS

FIG. 1 is a cross-sectional view illustrating a quantum dot according to an embodiment of the present disclosure;

FIG. 2 is a cross-sectional view illustrating the quantum dot according to another embodiment of the present disclosure;

FIG. 3 is a cross-sectional view illustrating the quantum dot according to another embodiment of the present disclosure;

FIG. 4 is a flowchart of a method of manufacturing the quantum dot according to another embodiment of the present disclosure;

FIG. 5 is a flowchart of the method of manufacturing the quantum dot according to another embodiment of the present disclosure;

FIG. 6 is a cross-sectional view illustrating an electronic device according to another embodiment of the present disclosure;

FIG. 7 is a cross-sectional view illustrating a light emitting diode according to another embodiment of the present disclosure;

FIG. 8 is a graph of an absorbance with respect to a wavelength of Examples 1 to 8 of the present disclosure; and

FIG. 9 is a graph of an absorbance with respect to a wavelength of Examples 9 to 14 and Comparative Examples 1 to 2 of the present disclosure.

### MODE FOR INVENTION

Hereinafter, some embodiments of the present disclosure will be described in detail with reference to the accompanying illustrative drawings. In designating elements of the drawings by reference numerals, the same elements will be designated by the same reference numerals although they are shown in different drawings. Further, in the following description of the present disclosure, a detailed description of known functions and configurations incorporated herein will be omitted in the case in which the subject matter of the present disclosure may be rendered unclear thereby.

It will be understood that the terms “comprise”, “have”, “consist of”, and any variations thereof used herein are intended to cover non-exclusive inclusions unless explicitly stated to the contrary. Descriptions of elements in the singular form used herein are intended to include descriptions of elements in the plural form, unless explicitly stated to the contrary.

In addition, terms, such as first, second, A, B, (a), or (b), may be used herein when describing elements of the present disclosure. Each of these terminologies is not used to define an essence, order, or sequence of a corresponding element but used merely to distinguish the corresponding element from other elements.

It will be understood that when an element is referred to as being “connected”, “coupled”, or “joined” to another element, not only can it be “directly connected, coupled, or joined” to the other element, but it can also be “indirectly connected, coupled, or joined” to the other element via an “intervening” element. Here, the intervening element may be included in one or more of the two elements “connected”, “coupled”, or “joined” to each other.

In addition, it will be understood that when an element is referred to as being “above” or “on” another element, not only can it be “directly” above or on the other element, but it can also be “indirectly” above or on the other element or layer via an “intervening” element. In contrast, when an element is referred to as being “directly” above or on another element, it will be understood that no intervening element is interposed. In addition, when an element is referred to as being “above” or “on” a reference portion, the element is positioned above or below the reference portion but is not necessarily positioned “above” or “on” the reference portion in the opposite direction of gravity.

When time relative terms, such as “after”, “subsequent to”, “next”, “before”, and the like, are used to describe elements, operating or manufacturing methods, and the like, these terms may be used to describe non-consecutive or non-sequential processes or operations unless the term “directly” or “immediately” is used together.

In addition, when any numerical values for elements or corresponding information are mentioned, it should be considered that numerical values for elements or corresponding information include a tolerance or error range that may be caused by various factors (e.g., process factors, internal or external impact, noise, etc.) even when a relevant description is not specified.

The “diameter” of a nanostructure refers to the diameter of a cross-section normal to a first axis of the nanostructure, where the first axis has the greatest difference in length with respect to the second and third axes (the second and third axes are the two axes whose lengths most nearly equal each other). The first axis is not necessarily the longest axis of the nanostructure; e.g., for a disk-shaped nanostructure, the cross-section would be a substantially circular cross-section normal to the short longitudinal axis of the disk. Where the cross-section is not circular, the diameter is the average of the major and minor axes of that cross-section. For an elongated or high aspect ratio nanostructure, such as a nanowire, the diameter is measured across a cross-section perpendicular to the longest axis of the nanowire. For a spherical nanostructure, the diameter is measured from one side to the other through the center of the sphere.

The term “quantum dot” (or “dot”) refers to a nanocrystal that exhibits quantum confinement or exciton confinement. Quantum dots can be substantially homogenous in material properties, or in certain embodiments, can be heterogeneous, e.g., including a core and at least one shell. The optical properties of quantum dots can be influenced by their particle size, chemical composition, and/or surface composition, and can be determined by suitable optical testing available in the art. The ability to tailor the nanocrystal size, e.g., in the range between about 1 nm and about 15 nm, enables photoemission coverage in the entire optical spectrum to offer great versatility in color rendering.

As used herein, the term “shell” refers to material deposited onto the core or onto previously deposited shells of the same or different composition and that result from a single act of deposition of the shell material. The exact shell thickness depends on the material as well as the precursor input and conversion and can be reported in nanometers or monolayers. As used herein, “target shell thickness” refers to the intended shell thickness used for calculation of the required precursor amount. As used herein, “actual shell thickness” refers to the actually deposited amount of shell material after the synthesis and can be measured by methods known in the art. By way of example, actual shell thickness can be measured by comparing particle diameters determined from transmission electron microscopy (TEM) images of nanocrystals before and after a shell synthesis.

The term “Group”, as used herein, refers to a group of Periodic Table. The term “Period”, as used herein, refers to a period of Periodic Table.

As used herein, “Group I” may refer to Group IA (or 1A) and Group IB (or 1B), and examples of Group I elements may include Li, Na, K, Rb, Cs, Cu, Ag and Au, but are not limited thereto.

“Group II” may refer to Group IIA (or 2A) and Group IIB (or 2B), and examples of Group II elements may include Be, Mg, Ca, Sr, Zn, Cd and Hg, but are not limited thereto.

“Group III” may refer to Group IIIA (or 3A) and Group IIIB (or 3B), and examples of Group III elements may include In, Ga, Al and Tl, but are not limited thereto.

“Group V” may refer to Group VA (or 5A), and examples of Group V elements may include P, As, Sb, Bi and N, but are not limited thereto.

“Group VI” may refer to Group VIA (or 6A), and examples of Group VI elements may include S, Se and Te, but are not limited thereto.

The term “precursor”, as used herein, means a chemical compound previously manufactured to cause a quantum dot to react. The precursor is a concept referring to all chemicals including metals, ions, elements, compounds, complexes, composites, clusters, and the like. The precursor is not necessarily limited to the last material of any reaction, but means a material that may be produced in any predetermined step.

Hereinafter, quantum dot according to embodiments of the present disclosure is described below with reference to the accompanying drawings.

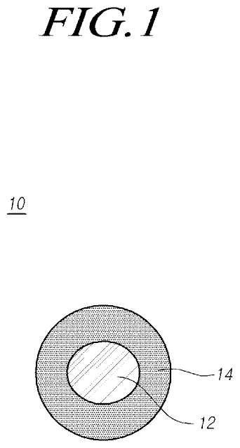

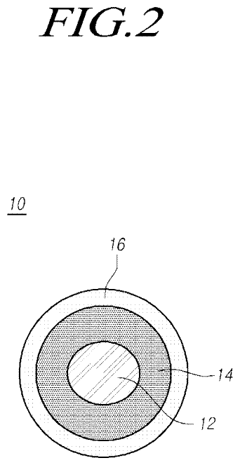

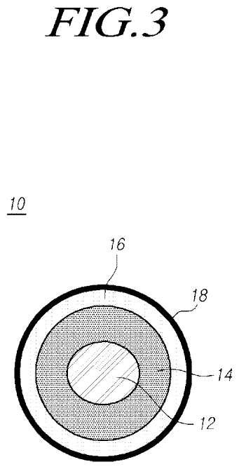

FIG. 1 is a cross-sectional view illustrating a quantum dot according to an embodiment of the present disclosure. FIG. 2 is a cross-sectional view illustrating the quantum dot according to another embodiment of the present disclosure. FIG. 3 is a cross-sectional view illustrating the quantum dot according to another embodiment of the present disclosure.

Referring to FIG. 1, a quantum dot 10 according to the embodiments of the present disclosure may include a core 12 and a shell 14. A quantum dot 10 according to another embodiments of the present disclosure may include a core 12, a first shell 14 and a second shell 16 as illustrated in FIG. 2, or may further include another shell 18 outside the second shell 16 as illustrated in FIG. 3, or may further include another intermediate shell (not shown) between the first shell 14 and the second shell 16. Hereinafter, as illustrated in FIG. 1, the quantum dot 10 including the core 12 and the shell 14 will be described. However, the description may be equally applied a quantum dot including a core/multilayer shell structure as illustrated in FIGS. 2 and 3.

The core 12 may include Ag, In, Ga and S. The core 12 may be doped with metals or non-metals. The core 12 may be purified before deposition of a shell 14. The core 12 may be filtered to remove precipitate from a core solution.

The shell 14 may be disposed on a core 12.

The quantum dot 10 may comprise the core 12 including silver (Ag), indium (In), gallium (Ga) and sulfur(S), and the shell 14 on the core 12, wherein the quantum dot may have an effective absorption efficiency defined by [Equation 1] of greater than or equal to 50%.

$$effective absorption efficiency ( \% ) = \frac{{Abs}_{300 nm ∼ 470 nm} \times {( QY )}^{2}}{10000} \times 100 \qquad [ Equation 1 ]$$

Wherein Equation 1, Abs_{300 nm˜470 nm} may be an integral value of an absorbance of a quantum dot in the range of 300 nm to 470 nm when an integral value of an absorbance of a quantum dot in the range of 300 nm to 800 nm is 1, and QY may be a quantum yield of a quantum dot.

Note that in Equation 1, it has been described that Abs_{300 nm˜470 nm} may be the integral value of the absorbance of the quantum dot in the range of 300 nm to 470 nm when the integral value of the absorbance of the quantum dot in the range of 300 nm to 800 nm is 1. However, Abs_{X1 nm˜X3 nm} may be the integral value of the absorbance of the quantum dot in the range of X1 nm to X3 nm when the integral value of the absorbance of the quantum dot in the entire range of X1 nm to X2 nm is 1. In this case, X1, X2, and X3 may be 300, 800, and 470 as in Equation 1, but may be varied as described below.

Since the larger the band gap energy, the light in the short wavelength region is emitted and high energy is required, the absorption value in the entire range X1 nm to X2 nm (e.g., 300 nm˜800 nm) is greater. The smaller the band gap energy, the light in the long wavelength region is emitted and the absorption value in the entire range is relatively smaller compared to the light emission in the short wavelength region.

In addition, the more light is emitted in the short wavelength range, the larger the integral value in the short wavelength range. The more light is emitted in the long wavelength range, the smaller the integral value in the short wavelength range.

For the display device, the blue wavelength for enabling the green quantum dot to emit light may be less than or equal to X3 nm, for example less than or equal to 470 nm. In this way, the overlap between the excitation wavelength and the emission wavelength required to enable luminescence can be avoided.

Since the absorbance in the short wavelength region differs depending on the emission wavelength, the effective absorption efficiency represents absorption according to quantum yield regardless of the emission wavelength by using the integral value of the absorbance from 300 nm to 470 nm when the integral value of the absorbance from 300 nm to 800 nm is 1.

Accordingly, the effective absorption efficiency quantifies the luminescence energy according to the degree of absorption of the quantum dot, and quantifies the value for the absorption rate compared to emission, rather than the emission compared to absorption. Accordingly, the quantum dot with a higher effective absorption efficiency is the quantum dot that absorbs better.

Since the above quantum dot 10 has the effective absorption efficiency defined by above [Equation 1] of greater than or equal to 50%, the above quantum dot 10 may be the quantum dot with good emission and absorption of light.

In addition, the quantum dot 10 may have the quantum yield of greater than or equal to 70% when the effective absorption efficiency may be greater than or equal to 50%. Conversely, the quantum dot 10 may have the effective absorption efficiency of greater than or equal to 50% and the quantum yield of greater than or equal to 70%. In this case, the quantum dot 10 may have the structure with a band gap alignment of type 1 or type 2 and the quantum yield of greater than or equal to 70%, and may exhibit good emission and absorption of light.

The shell 14 may include at least one of a Group I element and a Group III element, and a Group VI element.

As described above, “Group I” may refer to Group IA (or 1A) and Group IB (or 1B), and examples of Group I elements may include Li, Na, K, Rb, Cs, Cu, Ag and Au, but are not limited thereto.

The Group I element included in the shell 14 may or may not be identical to Ag included in the core 12. Since the shell 14 simultaneously includes the Group I element included in the core 12, vacancy defects on the surface of the core 12 may be removed or supplemented.

The shell 14 may include one Group I element or may include two or more different Group I elements. For example, in the case of the shell 14 including two or more different Group I elements, the shell 14 may include the Group IA (or 1A) element and the Group IB (or 1B) element. As an example, the Group IA (or 1A) element may be Na, and the Group IB (or 1B) element may be Cu or Ag.

Since the shell 14 includes the Group I element included in the core 12, vacancy defects on the surface of the core 12 may be removed or supplemented.

As described above, “Group III” may refer to Group IIIA (or 3A) and Group IIIB (or 3B), and examples of Group III elements may include In, Ga, Al and Tl, but are not limited thereto. “Group VI” may refer to Group VIA (or 6A), and examples of Group VI elements may include S, Se and Te, but are not limited thereto.

The shell 14 may be doped with metals or non-metals. The core 12/shell 14 may be purified after deposition of the shell 14. The core 12/shell 14 may be filtered to remove precipitate from a core solution.

The shell 14 may include one of AgAlS, AgAlSe, AgAlTe, AgGaS, AgGaSe, AgGaTe, AgInS, AgInSe, AgInTe, AgTiS, AgTiSe, AgTiTe, CuAlS, CuAlSe, CuAlTe, CuGaS, CuGaSe, CuGaTe, CuInS, CuInSe, CuInTe, CuTiS, CuTiSe, CuTiTe, AuAlS, AuAlSe, AuAlTe, AuGaS, AuGaSe, AuGaTe, AuInS, AuInSe, AuInTe, AuTiS, AuTiSe, and AuTiTe.

The shape or form of the quantum dot 10 is not particularly limited and may be any form available in the art. More specifically, the quantum dot 10 may be shaped as a spherical, pyramidal, multi-arm, or cubic nanoparticle, nanotube, nanowire, nanofiber, or nanoplatelet particle.

The quantum dot 10 may adjust the color of the emitted light according to the particle size, and accordingly, the quantum dot 10 may have various emission colors such as blue, red, and green.

According to an embodiment, the diameter of the quantum dot 10 may be 2 nm to 20 nm. The diameter of the quantum dot 10 may be 2 nm to 8 nm.

FIG. 2 is a cross-sectional view illustrating a quantum dot according to another embodiment of the present disclosure. FIG. 3 is a cross-sectional view illustrating a quantum dot according to another embodiment of the present disclosure.

Referring to FIGS. 2 and 3, the quantum dot 10 according to another embodiments of the present disclosure may include the core 12, the first shell 14 and the second shell 16, or may further include another shell 18 outside the second shell 16, or may further include another intermediate shell (not shown) between the first shell 14 and the second shell 16.

The core 12 and the first shell 14 of the quantum dot 10 according to another embodiments of the present disclosure may be substantially the same as the core 12 and the shell 14 described with reference to FIG. 1. In other words, the quantum dot 10 including the core 12 and the shell 14 as illustrated in FIG. 1 may be equally applied the quantum dot 10 having a core/multilayer shell structure as illustrated in FIGS. 2 and 3.

The second shell 16 may surround the first shell 14 while being positioned on the first shell 14 and may include at least one of Group III elements and at least one of Group VI elements. The Group III element included in the second shell 16 may or may not be identical to In and Ga included in the core. The Group VI element included in the second shell 16 may or may not be identical to S included in the core.

The second shell 16 may include the Group III element and at least one Group VI elements but may not include the Group I element included in the first shell 14. The Group VI element included in the first shell 14 may be identical to or may be different from the Group VI element included in the second shell 16.

The first shell 14 may be disposed on the core 12. The first shell 14 may include the Group I element and the Group III element, and the Group VI element. The second shell 16 may be disposed on the first shell 14. The second shell 16 may include the Group III element and the Group VII element. In this case, the Group III element and the Group VI element included in the first shell and the second shell may be the same or different.

The second shell 16 may additionally include another doped Group III element.

The first shell 14 and the second shell 16 simultaneously include the Group III element and at least one Group VI elements included in the core 12, but the second shell 16 does not include the Group I element included in the core 12 and the first shell 14. Since the first shell 14 including the Group I element is not exposed to the outside, the Group I element included in the first shell 14 may be prevented from oxidation.

Since the first shell 14 includes the Group I element included in the core 12, vacancy defects on the surface of the core 12 may be removed or supplemented. Since the second shell 16 surrounds the first shell 14 and does not include the Group I element, oxidation of the Group I element included in the first shell 14 is prevented, therefore ultimately ensuring the stability of the quantum dot 10.

Since the quantum dot 10 according to the embodiments of the present disclosure includes only the components of the above elements and a multilayer shell including the first shell 14 and the second shell 14, vacancy defects on the surface of the core 12 may be removed or supplemented and oxidation of the Group I element included in the first shell 14 may be prevented.

Since the first shell 14 including the Group I element has a higher affinity for the core 12 than the second shell 16, the first shell 14 may be formed thicker relatively more easily.

As described above, as the first shell 14 is stacked, the Group I elements are likely to diffuse outward and be oxidized, which makes the stability of the quantum dot vulnerable. By stacking the second shell 16 which includes the Group III elements and at least one Group VI element included in the core 12 but does not include the Group I elements included in the core 12 and the first shell 14, the oxidation of the Group I elements included in the core 12 and the first shell 14 may be prevented, thereby improving the stability.

In this case, since the second shell 16 may be formed entirely in an amorphous state, the second shell 16 becomes thicker than a certain thickness, the crystallinity may weaken and the stability may decrease.

That is, the first shell 14 may be formed thickly because the crystallinity is improved due to the Group I element and thus becomes structurally stable and the second shell 16 may not be made thicker than a certain thickness because the second shell 16 is formed entirely amorphous, so that the crystallinity of the first shell 14 and the second shell 16 may be improved overall.

In the quantum dot 10 according to embodiment, a thickness of the first shell 14 may be relatively thicker than a thickness of the second shell 16. Accordingly, the Group I element of the first shell 14 may improve the crystallinity of the first shell 14, and the crystallinity of the second shell 16, which may be formed in an amorphous state, may also be improved at the same time.

The thickness of the first shell 14 may be 2.9 nm to 4.2 nm and the thickness of the second shell 16 may be 0.8 nm to 2.5 nm. In addition, the thickness of the first shell 14 may be 2.9 nm to 3.9 nm and the thickness of the second shell 16 may be 0.8 nm to 1.6 nm.

Since the thickness of the first shell 14 may be 2.9 nm to 4.2 nm and the thickness of the second shell 16 may be 0.8 nm to 2.5 nm, a full width at half maximum and a quantum yield of the quantum dot composed of multilayer shell may be improved. At the same time, the surface stability of the quantum dot may be increased as the crystallinity of the quantum dot may be high, and the luminescence efficiency and the stability of the quantum dot may be improved.

In one aspect, at least one Group I element included in the first shell 14 may not be oxidized. Since the quantum dot 10 includes the second shell 16 surrounding the first shell 14 and the second shell 16 does not include the Group I element that is easily oxidized, the Group I element included in the first shell 14 may not be oxidized.

The first shell 14 may be entirely crystalline, and the second shell 16 may be entirely amorphous. As used herein, the term “entirely” crystalline or amorphous means that more than 70% of the shell may be crystalline or amorphous, more than 85% of the shell may be crystalline or amorphous, or more than 95% of the shell may be crystalline or amorphous.

In addition, the second shell 16 may include one of AIS, AlSe, AlTe, GaS, GaSe, GaTe, InS, InSe, InTe, TiS, TiSe, and TiTe.

In another aspect, embodiments of the present disclosure may provide a method of manufacturing a quantum dot.

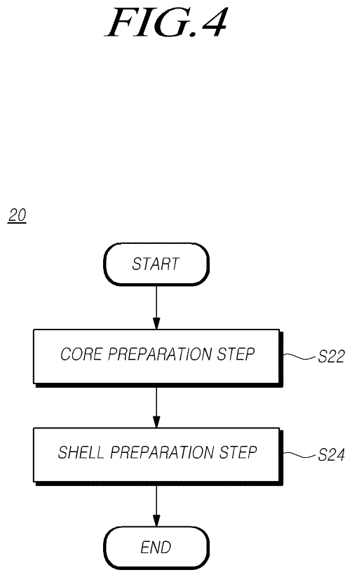

FIG. 4 is a flowchart of a method of manufacturing a quantum dot according to another embodiment of the present disclosure.

Referring to FIG. 4, the method 20 of manufacturing the quantum dot according to embodiments of the present disclosure may comprise a core preparation step S22 and a shell preparation step S24.

In the method 20 of manufacturing the quantum dot according to embodiments of the present disclosure, features of the core and the shell are the same as those of the core 12, and the shell 14 described for the quantum dot 10 according to above embodiments, unless clearly stated otherwise.

The method 20 of manufacturing the quantum dot may be performed by preparing a core using a silver precursor, an indium precursor, a gallium precursor, and a sulfur precursor in a heated reactor, and then by preparing the prepared core together with a precursor for preparing a shell using a hot-injection method and a heating up method. In addition, the hot-injection method and the heating up method may be performed in each step of the core preparation step S22 and the shell preparation step S24.

The core preparation step S22 may be a step of preparing the core by injecting and reacting the silver precursor, the indium precursor, the gallium precursor, the sulfur precursor and the solvent in the first reactor.

The shell preparation step S24 may be a step of preparing the shell by injecting and reacting the prepared core in the second reactor containing the precursor including specific elements.

The quantum dot prepared by the core preparation step S22 and the shell preparation step S24 may have an effective absorption efficiency defined by above [Equation 1] of greater than or equal to 50%.

Since the prepared quantum dot may have an effective absorption efficiency defined by above [Equation 1] of greater than or equal to 50%, the prepared quantum dot may be a quantum dot with good emission and absorption of light.

In addition, the quantum dot 10 may have a quantum yield of greater than or equal to 70% when an effective absorption efficiency may be greater than or equal to 50%. Conversely, the quantum dot 10 may have the effective absorption efficiency of greater than or equal to 50% and the quantum yield of greater than or equal to 70%. In this case, the quantum dot 10 may have the structure with a band gap alignment of type 1 or type 2 and the quantum yield of greater than or equal to 70%, and may exhibit good emission and absorption of light.

Specific elements may include at least one of the Group I element and the Group III element; and the Group VI element.

In this case, the shell preparation step S24 may be a step of preparing the shell by injecting and reacting the prepared core in the second reactor containing at least one of the Group I precursor including the Group I element and the Group III precursor including the Group III element and the Group VI precursor including the Group VI element.

The core preparation step S22 may be a step of preparing the core. The core preparation step may comprise a step 1-1 and a step 1-2.

The step 1-1 may be a step of preparing the core solution by injecting and heating the silver precursor, the indium precursor, the gallium precursor, the sulfur precursor and the solvent in the first reactor.

The silver precursor injected in the step 1-1 may include, for example, one or more selected from silver (I) acetylacetonate, silver (I) chloride, silver (I) bromide, silver (I) iodide, silver (I) acetate, silver (I) nitrate, and silver (I) myristate.

The indium precursor injected in the step 1-1 may include, for example, one or more selected from indium (III) acetylacetonate, indium (III) chloride, indium (III) acetate, trimethyl indium, alkyl indium, aryl indium, indium (III) myristate, and indium (III) myristate acetate.

The gallium precursor injected in the step 1-1 may include, for example, one or more selected from gallium (III) acetylacetonate, gallium (III) chloride, gallium (III) iodide, gallium (III) bromide, gallium (III) acetate, and gallium (III) nitrate.

The sulfur precursor injected in the step 1-1 may include, for example, one or more selected from alkyl thiols, such as n-butanethiol, isobutane thiol, n-haxanethiol, 1-octanethiol, decanethiol, 1-dodecanethiol, hexadecanethiol, and octadecanethiol, sulfur chloride, sulfur(S), S-TOP, S-ODE, S-toluene, S-oleylamine, and N,N-dimethylthiourea.

The solvent injected in the step 1-1 may include, for example, one or more selected from oleylamine, 1-octadecene, and trioctylamine, but are not limited thereto.

The silver precursor, the indium precursor, the gallium precursor, and the sulfur precursor injected in the step 1-1 may each be precursor solution mixed with the solvent.

The core solution including the core may be prepared by the step 1-1, and the core may be formed by reacting the silver precursor, the indium precursor, the gallium precursor, and the sulfur precursor in the second reactor.

The step 1-2 may be a step of adding a purification solvent to the core solution and centrifuging a resulting product, and dispersing a precipitate separated through centrifugation in a dispersion solvent.

For example, the step 1-2 may be a step of adding the purification solvent, such as methanol, ethanol, acetone, and 2-propanol (IPA), to the core solution and centrifuging the resulting product, and dispersing the precipitate separated through centrifugation in the dispersion solvent, such as hexane, toluene, octadecane, heptane, oleylamine, and 1-octadecene.

The purified core solution may be prepared by the step 1-2.

The shell preparation step S24 may comprise a step 2-1 and a step 2-2.

The step 2-1 may be a step of injecting at least one of Group III precursors, such as aluminum precursor, indium precursor, gallium precursor, and thallium precursor, in the second reactor containing an oleyamine.

The step 2-2 may be a step of injecting and reacting the purified core solution and at least one of sulfur precursor, selenium precursor and tellurium precursor in the second reactor.

The Group I element in the shell may include one or more selected from Li, Na, Cu, Ag, and Au, but are not limited thereto. The Group III element may include one or more selected from In, Ga, Al, and Tl, but are not limited thereto. The Group VI element may include one or more selected from S, Se, and Te, but are not limited thereto.

The shell preparation step S24 may be a step of preparing the first shell by injecting and reacting the prepared core and the Group VI precursor in the second reactor containing the Group I precursor including at least one Group I element and the Group III precursor including at least one Group III element.

The shell preparation step S24 may comprise a step 2-1 and a step 2-2.

The step 2-1 may be a step of injecting the Group I precursor including at least one Group I element and the Group III precursor including at least one Group III element in the second reactor containing an oleylamine.

The step 2-2 may be a step of reacting the purified core solution and the Group VI precursor in the first reactor.

The first precursor injected in a step 2-1 may include, e.g., one or more selected from the group consisting of chloride, iodide, oxide and acetylacetonate chemically bonded with at least one Group I element.

For example, when the Group I element is Ag, the first precursor may be silver (I) chloride, silver (I) iodide, silver (I) oxidee, or silver (I) acetylacetonate.

The Group III precursor and the Group VI precursor injected in the step 2-1 and the step 2-2 may include, e.g., one or more selected from the group consisting of acetate, acetylacetonate, oxide, bromide, chloride and iodide chemically bonded with at least one Group III element.

For example, when the Group III precursor injected in the step 2-1 is a gallium precursor, the gallium precursor may be one or more selected from the group consisting of gallium (III) acetate, gallium (III) acetylacetonate, gallium (III) oxide, gallium (III) bromide, gallium (III) chloride, and gallium (III) iodide.

When the Group III precursor injected in the step 2-1 is an indium precursor, the indium precursor has already been described in connection with the step 1-1, and thus a description thereof will be omitted.

When the Group VI precursor injected in the step 2-2 is a sulfur precursor, the sulfur precursor has already been described in connection with the step 1-1, and thus a description thereof will be omitted.

When the Group VI precursor injected in the step 2-2 is a selenium precursor, the selenium precursor may be, e.g., one or more selected from the group consisting of selenium chloride, selenium (Se), Se-TOP, Se-DPP, Se-ODE, and organic selenium compounds, e.g., compounds such as dibenzyl diselenide, diphenyl diselenide, or selenium hydride.

When the Group VI precursor injected in the step 2-2 is a tellurium precursor, the tellurium precursor may be, e.g., one or more selected from the group consisting of tellurium chloride, tellurium (Te), and tellurium hydride.

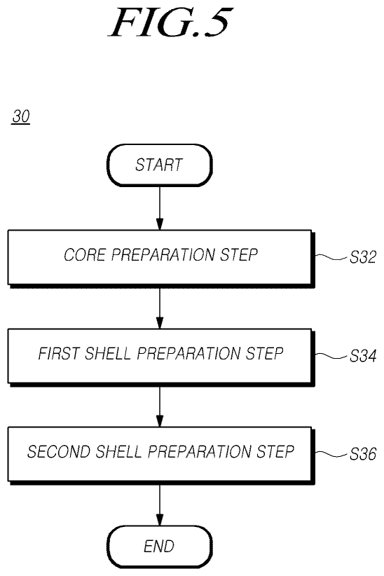

Referring to FIG. 4, the method of manufacturing the quantum dot 10 including the core 12 and the shell 14 as illustrated in FIG. 1 was described. Hereinafter, referring to FIG. 5, the method of manufacturing the quantum dot 10 including the core 12 and the shells 14 and 16 as illustrated in FIG. 2 is described. The quantum dot 10 including the core 12 and three shells 14, 16, and 18 as illustrated in FIG. 3 may be manufactured by adding an outermost shell 18 to the method of manufacturing the quantum dot 10 described with reference to FIG. 5.

FIG. 5 is a flowchart of a method of manufacturing a quantum dot according to another embodiment of the present disclosure.

Referring to FIG. 5, the method 30 of manufacturing the quantum dot according to embodiments of the present disclosure may comprise a core preparation step S32, a first shell preparation step S34, and a second shell preparation step S36.

In the method 30 of manufacturing the quantum dot according to embodiments of the present disclosure, features of the core and the first shell, the second shell are the same as those of the core 12, and the first shell 14, the second shell 16 described for the quantum dot 10 according to above embodiments, unless clearly stated otherwise.

The core preparation step S32 and the first shell preparation step S34 may be substantially the same as the core preparation step S22 and the shell preparation step S24 described with reference to FIG. 4.

The second shell preparation step S36 may be a step of preparing the second shell surrounding the first shell by injecting and reacting the prepared core/first shell in the second reactor containing the Group III precursor including at least one Group III element and the Group VI precursor including at least one Group VI element.

The Group III element included in the second shell may include one or more selected from In, Ga, Al, and Tl, but are not limited thereto. The Group VI element included in the second shell may include one or more selected from S, Se, and Te, but are not limited thereto. The Group VI element included in the second shell may or may not be identical to S included in the core.

The Group III precursor including Group III element and the Group VI precursor including at least one Group VI element used in the second shell preparation step S36 may be the Group III precursor and the Group VI precursor described in the first shell preparation step S34.

The thickness of the first shell prepared in the first shell preparation step S34 may be 2.9 nm to 4.2 nm and the thickness of the second shell prepared in the second shell preparation step S36 may be 0.8 nm to 2.5 nm. In addition, the thickness of the first shell prepared in the first shell preparation step S34 may be 2.9 nm to 3.9 nm and the thickness of the second shell prepared in the second shell preparation step S36 may be 0.8 nm to 1.6 nm.

The first shell prepared in the first shell preparation step S34 may be entirely crystalline, and the second shell prepared in the second shell preparation step S36 may be entirely amorphous.

In another aspect, in the quantum dot according to another embodiment, the thickness of the first shell prepared in the first shell preparation step S34 may be relatively thicker than the thickness of the second shell prepared in the second shell preparation step S36.

The first shell prepared in the first shell preparation step S34 may include one of AgAlS, AgAlSe, AgAlTe, AgGaS, AgGaSe, AgGaTe, AgInS, AgInSe, AgInTe, AgTiS, AgTiSe, AgTiTe, CuAlS, CuAlSe, CuAlTe, CuGaS, CuGaSe, CuGaTe, CuInS, CuInSe, CuInTe, CuTiS, CuTiSe, CuTiTe, AuAlS, AuAlSe, AuAlTe, AuGaS, AuGaSe, AuGaTe, AuInS, AuInSe, AuInTe, AuTiS, AuTiSe, and AuTiTe.

In addition, the second shell prepared in the second shell preparation step S36 may include one of AlS, AlSe, AlTe, GaS, GaSe, GaTe, InS, InSe, InTe, TiS, TiSe, and TiTe.

In another aspect, according to embodiments of the present disclosure, there may be provided an ink composition comprising the quantum dot 10 described with reference to FIGS. 1 to 3 or the quantum dot prepared in the method described with reference to FIGS. 4 and 5. In the ink composition according to embodiments of the present disclosure, the quantum dot is the same as the quantum dot 10 according to embodiments of the disclosure unless otherwise described.

The ink composition according to the present embodiments may be a light conversion ink composition including quantum dots 10, a light curable monomer, a light initiator, and a light diffuser.

According to an embodiment, the content of the quantum dot 10 may be 20 parts by weight to 60 parts by weight, e.g., 25 parts by weight to 50 parts by weight, or 30 parts by weight to 45 parts by weight, with respect to the total content of 100 parts by weight of the quantum dot ink composition. According to an embodiment, the ink composition may not include a solvent. In other words, the ink composition may be a solvent-free quantum dot ink composition. According to an embodiment, the ink composition may have a viscosity of 10 cP to 25 cP. According to an embodiment, the surface tension of the ink composition at 25° C. may be 30 mN/m or more. When the above viscosity and/or surface tension range is satisfied, the ink composition, as a solvent-free quantum dot ink composition, may appropriately use various members, such as a color conversion member or an emission layer of an emission device, in a solution process such as an inkjet.

According to an embodiment, an optical member formed using an ink composition may be provided. For example, the optical member may be a color conversion member.

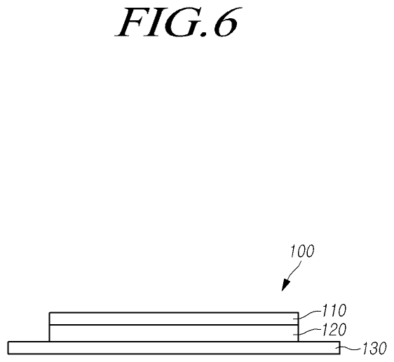

According to another aspect, referring to FIG. 6, an electronic device 100 according to an embodiment may include a substrate 110, a light source 120 disposed on the substrate 110, and a color conversion member 130 disposed in a path of light emitted from the light source 120, and the color conversion member 130 may be formed using the above ink composition.

According to an embodiment, the light source 120 may be an emission device. For example, the light source 120 may be an organic light emitting diode (OLED) or an inorganic light emitting diode (ILED or QLED).

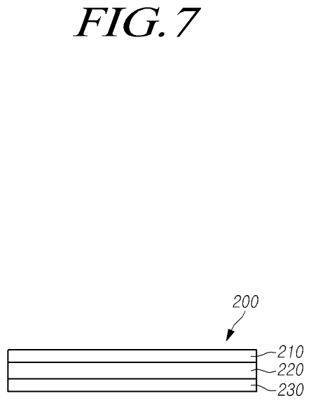

In another aspect, referring to FIG. 7, the light emitting diode 200 according to another embodiment may include quantum dot 10. The light emitting diode 200 according to other embodiments may include a positive electrode 210, a negative electrode 230, and an intermediate layer 220 positioned therebetween. The intermediate layer 220 may include an emission layer including an ink composition including the above quantum dot.

According to another aspect of the disclosure, there may be provided an electronic device including a display device including the above light emitting diode and a controller for driving the display device.

The electronic device may include, e.g., a display device, a lighting device, a solar cell, a portable or mobile terminal (e.g., a smartphone, a tablet, a PDA, an electronic dictionary, a PMP, etc.), a navigation terminal, a game console, various TVs, various computer monitors, etc., but without limitations thereto, may include any type of device that includes the component(s).

Applications to various electronic devices and devices using quantum dot 10 may be easily applied by those skilled in the art, and thus detailed descriptions thereof will be omitted.

Hereinafter, specific embodiments are presented. However, the embodiments described below are merely for specifically illustrating or describing the disclosure, and the scope of the disclosure is not limited thereto.

The examples below describe the method for manufacturing a quantum dot 10 including the core 12 and first and second shells 14 and 16 described with reference to FIG. 2.

In this case, the description may refer to an example in which the Group I element is Ag, the Group III element is Ga, and the Group VI element is S, used in the first shell 14 and the second shell 16. In other words, an example of manufacturing AgInGaS/AgGaS/GaS quantum dot may be exemplarily described.

Since the method for manufacturing the core 12 and the first and second shells 14 and 16 in the same manner as in the examples below using the elements described in the above-described examples may be typical technologies, the detailed descriptions thereon are omitted.

The quantum dot 10 as illustrated in FIG. 1 may be the quantum dot prepared the core 12 and the first shell 14, and the quantum dot 10 as illustrated in FIG. 3 may be the quantum dot prepared the core 12 and the first and second shells 14 and 16 adding an outermost shell 18.

### Embodiment

### (1) Preparing Precursors

### (Preparation Example 1) Preparing Silver (I) Iodide-Oleylamine Precursor Solution

0.56 g (2.4 mmol) of silver (I) iodide and 10 mL (30 mmol) of oleylamine were placed in a 50 mL flask, decompressed at room temperature (RT) for 1 hour, heated to 120° C. for 10 minutes, and then reacted for 1 hour. The mixed solution was cooled to room temperature in an Ar atmosphere to prepare an Ag precursor solution. The Ag concentration of the precursor solution was 0.24 M.

### (Preparation Example 2) Preparing Indium (III) Chloride-Ethanol Precursor Solution

0.11 g (0.5 mmol) of indium (III) chloride and 5 mL of ethanol were placed in 10 mL vial to prepare an In precursor solution. The In concentration of the precursor solution was 0.10 M.

### (Preparation Example 3): Preparing Gallium (III) Chloride-Toluene Precursor Solution

0.80 g (4.54 mmol) of gallium (III) chloride and 0.8 mL of toluene were placed in 10 mL vial to prepare a Ga precursor solution. The Ga concentration of the precursor solution was 5.68 M.

### (Preparation Example 4) Preparing Gallium (III) Acetylacetonate-Toluene Precursor Solution

1.67 g (4.54 mmol) of gallium (III) chloride and 16 mL of toluene were placed in 20 mL vial to prepare a Ga precursor solution. The Ga concentration of the precursor solution was 0.28 M.

### (Preparation Example 5) Preparing S-Oleylamine Precursor Solution

0.305 g (9.5 mmol) of S and 9.5 mL (28.5 mmol) of oleylamine were placed in a 50 mL flask, decompressed at room temperature (RT) for 30 minutes, heated to 120° C. for 10 minutes, and then reacted for 1 hour. The mixed solution was cooled to room temperature in an Ar atmosphere to prepare an S precursor solution. The S concentration of the precursor solution was 1 M.

### (Preparation Example 6: Preparing AgInGaS Quantum Dot Core

(1) 0.3 g of gallium (III) acetylacetonate and trioctylphosphine oxide (TOPO) prepared in Preparation Example 4, 5 ml of silver (I) iodide-oleylamine prepared in Preparation Example 1, indium (III) chloride-ethanol prepared in Preparation Example 2 and 1-octadecene were placed in a round flask of 50 mL having a refluxer and heated to 120° C. while being maintained at about 0.005 torr using a vacuum pump for 30 minutes.

(2) Then, after substituting with an N₂ atmosphere, 1 ml (0.03 g, 1 mmol) of the S-oleylamine solution prepared in Preparation Example 5 and 0.5 ml of 1-dodecanethiol were injected at 120° C.

(3) After the S-oleylamine solution was added, it was maintained at 0.005 torr using a vacuum pump at 120° C. for 30 minutes. Then, the reaction was terminated after stirring at 190° C. for 10 minutes.

(4) 5 ml of tris dimethylamino phosphine ((PDEA)₃)+trioctylphosphine (TOP) mixed solution was injected at 280° C. and was then cooled to room temperature.

(5) The prepared AgInGaS quantum dot solution was divided into two and was filled with 42.5 ml of ethanol, preparing 50 ml of AgInGaS core-ethanol solution.

(6) The solution was centrifuged at 5000 RPM for 5 minutes and then dispersed in 1.2 ml of toluene. The dispersed AgInGaS core-toluene solution was centrifuged at 5000 RPM for 1 minute to remove impurities, obtaining an AgInGaS core quantum dot solution.

### (2) Example 1: Preparing AgInGaS/AgGaS/GaS Quantum Dots

(1) In the process of Preparation Example 6, an AgInGaS quantum dot core solution was prepared using 0.9575 ml (Ag: 0.23 mmol) of silver (I) iodide-oleylamine, 2.5 ml (In: 0.25 mmol) of indium (III) chloride-ethanol, and 0.146 g (Ga: 0.4 mmol) of gallium (III) acetylacetonate.

(2) 16 ml of oleylamine was prepared in a 50 mL 3-neck round flask with a refluxer, heated to 120° C., and maintained at 0.005 torr using a vacuum pump for 30 minutes. After substitution with a nitrogen atmosphere at 120° C., the AgInGaS quantum dot core solution of 1) was injected, 0.8 ml 0.80 g, 4.54 mmol of gallium (III) chloride-toluene solution prepared in Preparation Example 3 and 0.014 g of silver (I) iodide, 2 ml of S-oleylamine were injected, and toluene was removed using a vacuum pump. Then, after substitution with a nitrogen atmosphere, the reaction proceeded at 310° C. for 60 minutes.

(3) 5 ml of tris dimethylamino phosphine (PDEA)₃)+trioctylphosphine (TOP) mixed solution was injected at 280° C. and cooled to room temperature, obtaining an AgInGaS/AgGaS quantum dot solution.

(4) 16 ml of oleylamine was prepared in a 50 mL 3-neck round flask with a refluxer, heated to 120° C., and maintained at 0.005 torr using a vacuum pump for 30 minutes. After substitution with a nitrogen atmosphere at 120° C., the AgInGaS/AgGaS quantum dot solution was injected, 0.8 ml of gallium (III) chloride-toluene solution and 2 ml of S-oleylamine were injected, and toluene was removed using a vacuum pump. Then, after substitution with a nitrogen atmosphere, the reaction proceeded at 310° C. for 100 minutes.

(5) 5 ml of tris dimethylamino phosphine (PDEA)₃)+trioctylphosphine (TOP) mixed solution was injected at 280° C. and cooled to room temperature, obtaining an AgInGaS/AgGaS/GaS quantum dot solution.

### (3) Example 2: Preparing AgInGaS/AgGaS/GaS Quantum Dots

Quantum dots were obtained in the same manner as in embodiment 1 except that 0.9575 ml (Ag: 0.23 mmol) of silver (I) iodide-oleylamine, 2.5 ml (In: 0.25 mmol) of indium (III) chloride-ethanol, and 0.146 g (Ga: 0.4 mmol) of gallium (III) acetylacetonate were used and stirred at 200° C. for 10 minutes in the process of Preparation Example 6.

### (4) Example 3: Preparing AgInGaS/AgGaS/GaS Quantum Dots

Quantum dots were obtained in the same manner as in embodiment 1 except that 0.9575 ml (Ag: 0.23 mmol) of silver (I) iodide-oleylamine, 2.5 ml (In: 0.25 mmol) of indium (III) chloride-ethanol, and 0.146 g (Ga: 0.4 mmol) of gallium (III) acetylacetonate were used and stirred at 210° C. for 10 minutes in the process of Preparation Example 6.

### (5) Example 4: Preparing AgInGaS/AgGaS/GaS Quantum Dots

Quantum dots were obtained in the same manner as in embodiment 1 except that 0.9575 ml (Ag: 0.23 mmol) of silver (I) iodide-oleylamine, 2.5 ml (In: 0.25 mmol) of indium (III) chloride-ethanol, and 0.146 g (Ga: 0.4 mmol) of gallium (III) acetylacetonate were used and stirred at 220° C. for 10 minutes in the process of Preparation Example 6.

### (6) Example 5: Preparing AgInGaS/AgGaS/GaS Quantum Dots

Quantum dots were obtained in the same manner as in embodiment 1 except that 0.9575 ml (Ag: 0.23 mmol) of silver (I) iodide-oleylamine, 2.5 ml (In: 0.25 mmol) of indium (III) chloride-ethanol, and 0.146 g (Ga: 0.4 mmol) of gallium (III) acetylacetonate were used and stirred at 230° C. for 10 minutes in the process of Preparation Example 6.

### (7) Example 6: Preparing AgInGaS/AgGaS/GaS Quantum Dots

Quantum dots were obtained in the same manner as in embodiment 1 except that 0.9575 ml (Ag: 0.23 mmol) of silver (I) iodide-oleylamine, 2.5 ml (In: 0.25 mmol) of indium (III) chloride-ethanol, and 0.146 g (Ga: 0.4 mmol) of gallium (III) acetylacetonate were used and stirred at 240° C. for 10 minutes in the process of Preparation Example 6.

### (8) Example 7: Preparing AgInGaS/AgGaS/GaS Quantum Dots

Quantum dots were obtained in the same manner as in embodiment 1 except that 0.9575 ml (Ag: 0.23 mmol) of silver (I) iodide-oleylamine, 2.5 ml (In: 0.25 mmol) of indium (III) chloride-ethanol, and 0.146 g (Ga: 0.4 mmol) of gallium (III) acetylacetonate were used and stirred at 250° C. for 10 minutes in the process of Preparation Example 6.

### (9) Example 8: Preparing AgInGaS/AgGaS/GaS Quantum Dots

Quantum dots were obtained in the same manner as in embodiment 1 except that 0.9575 ml (Ag: 0.23 mmol) of silver (I) iodide-oleylamine, 2.5 ml (In: 0.25 mmol) of indium (III) chloride-ethanol, and 0.146 g (Ga: 0.4 mmol) of gallium (III) acetylacetonate were used and stirred at 260° C. for 10 minutes in the process of Preparation Example 6.

### (10) Example 9: Preparing AgInGaS/AgGaS/GaS Quantum Dots

Quantum dots were obtained in the same manner as in embodiment 1 except that 1.67 ml (Ag: 0.4 mmol) of silver (I) iodide-oleylamine, 2.4 ml (In: 0.24 mmol) of indium (III) chloride-ethanol, and 0.0697 g (Ga: 0.19 mmol) of gallium (III) acetylacetonate were used and stirred at 200° C. for 10 minutes in the process of Preparation Example 6.

### (11) Example 10: Preparing AgInGaS/AgGaS/GaS Quantum Dots

Quantum dots were obtained in the same manner as in embodiment 1 except that 1.67 ml (Ag: 0.4 mmol) of silver (I) iodide-oleylamine, 2.5 ml (In: 0.25 mmol) of indium (III) chloride-ethanol, and 0.0697 g (Ga: 0.19 mmol) of gallium (III) acetylacetonate were used and stirred at 200° C. for 10 minutes in the process of Preparation Example 6.

### (12) Example 11: Preparing AgInGaS/AgGaS/GaS Quantum Dots

Quantum dots were obtained in the same manner as in embodiment 1 except that 1.67 ml (Ag: 0.4 mmol) of silver (I) iodide-oleylamine, 2.4 ml (In: 0.24 mmol) of indium (III) chloride-ethanol, and 0.0697 g (Ga: 0.19 mmol) of gallium (III) acetylacetonate were used and stirred at 210° C. for 10 minutes in the process of Preparation Example 6.

### (13) Example 12: Preparing AgInGaS/AgGaS/GaS Quantum Dots

Quantum dots were obtained in the same manner as in embodiment 1 except that 1.67 ml (Ag: 0.4 mmol) of silver (I) iodide-oleylamine, 2.5 ml (In: 0.24 mmol) of indium (III) chloride-ethanol, and 0.0697 g (Ga: 0.19 mmol) of gallium (III) acetylacetonate were used and stirred at 210° C. for 10 minutes in the process of Preparation Example 6.

### (14) Example 13: Preparing AgInGaS/AgGaS/GaS Quantum Dots

Quantum dots were obtained in the same manner as in embodiment 1 except that 1.67 ml (Ag: 0.4 mmol) of silver (I) iodide-oleylamine, 2.4 ml (In: 0.24 mmol) of indium (III) chloride-ethanol, and 0.0697 g (Ga: 0.19 mmol) of gallium (III) acetylacetonate were used and stirred at 220° C. for 10 minutes in the process of Preparation Example 6.

### (15) Example 14: Preparing AgInGaS/AgGaS/GaS Quantum Dots

Quantum dots were obtained in the same manner as in embodiment 1 except that 1.67 ml (Ag: 0.4 mmol) of silver (I) iodide-oleylamine, 2.5 ml (In: 0.25 mmol) of indium (III) chloride-ethanol, and 0.0697 g (Ga: 0.19 mmol) of gallium (III) acetylacetonate were used and stirred at 220° C. for 10 minutes in the process of Preparation Example 6.

### (16) Comparative Example 1: Preparing AgInGaS/AgGaS Quantum Dots

(1) In the process of Preparation Example 6, an AgInGaS quantum dot core solution was prepared using 0.9575 ml (Ag: 0.23 mmol) of silver (I) iodide-oleylamine, 2.5 ml (In: 0.25 mmol) of indium (III) chloride-ethanol, and 0.146 g (Ga: 0.4 mmol) of gallium (III) acetylacetonate.

(2) 16 ml of oleylamine was prepared in a 50 mL 3-neck round flask with a refluxer, heated to 120° C., and maintained at 0.005 torr using a vacuum pump for 30 minutes. After substitution with a nitrogen atmosphere at 120° C., the AgInGaS quantum dot core solution of 1) was injected, 0.8 ml 0.80 g, 4.54 mmol of gallium (III) chloride-toluene solution prepared in Preparation Example 3 and 0.014 g of silver (I) iodide, 2 ml of S-oleylamine were injected, and toluene was removed using a vacuum pump. Then, after substitution with a nitrogen atmosphere, the reaction proceeded at 310° C. for 60 minutes.

(3) 5 ml of tris dimethylamino phosphine (PDEA) 3)+trioctylphosphine (TOP) mixed solution was injected at 280° C. and cooled to room temperature, obtaining an AgInGaS/AgGaS quantum dot solution.

### (17) Comparative Example 2: Preparing AgInGaS/GaS/AgGaS Quantum Dots

(1) In the process of Preparation Example 6, an AgInGaS quantum dot core solution was prepared using 0.9575 ml (Ag: 0.23 mmol) of silver (I) iodide-oleylamine, 2.5 ml (In: 0.25 mmol) of indium (III) chloride-ethanol, and 0.146 g (Ga: 0.4 mmol) of gallium (III) acetylacetonate.

(2) 16 ml of oleylamine was prepared in a 50 mL 3-neck round flask with a refluxer, heated to 120° C., and maintained at 0.005 torr using a vacuum pump for 30 minutes. After substitution with a nitrogen atmosphere at 120° C., the AgInGaS quantum dot core solution of 1) was injected, 0.8 ml of gallium (III) chloride-toluene solution and 2 ml of S-oleylamine were injected, and toluene was removed using a vacuum pump. Then, after substitution with a nitrogen atmosphere, the reaction proceeded at 310° C. for 100 minutes.

(3) 5 ml of tris dimethylamino phosphine (PDEA) 3)+trioctylphosphine (TOP) mixed solution was injected at 280° C. and cooled to room temperature, obtaining an AgInGaS/GaS quantum dot solution.

(4) 16 ml of oleylamine was prepared in a 50 mL 3-neck round flask with a refluxer, heated to 120° C., and maintained at 0.005 torr using a vacuum pump for 30 minutes. After substitution with a nitrogen atmosphere at 120° C., the AgInGaS/GaS quantum dot solution was injected, 0.8 ml of gallium (III) chloride-toluene solution and 0.014 g of silver (I) iodide, 2 ml of S-oleylamine were injected, and toluene was removed using a vacuum pump. Then, after substitution with a nitrogen atmosphere, the reaction proceeded at 310° C. for 100 minutes.

(5) 5 ml of tris dimethylamino phosphine (PDEA) 3)+trioctylphosphine (TOP) mixed solution was injected at 280° C. and cooled to room temperature, obtaining an AgInGaS/GaS/AgGaS quantum dot solution.

### EXPERIMENTAL EXAMPLE

For the quantum dots manufactured as above according to Examples 1 to 14 and Comparative Examples 1 to 2, the integral value of the absorbance of the quantum dot with respect to the wavelength, the optical characteristics of the quantum dots [Emission Peak, Quantum Yield, Full Width at Half Maximum (FWHM)] and the effective absorption efficiency were confirmed using the QE-2000 device of Otsuka Electronics.

Table 1 below illustrates the evaluation results of the optical characteristics of the prepared quantum dots.

TABLE 1

| | (1) integral value | (2) integral value | | | | |
|---|---|---|---|---|---|---|
| | of an absorbance | of an absorbance | | | | effective |
| | of the quantum dot | of the quantum dot | Emission | | | absorption |
| | in the range of 300 | in the range of 300 | peak | FWHM | QY | efficiency |
| | nm to 800 nm | nm to 470 nm | (nm) | (nm) | (%) | (%) |
| Example 1 | 1 | 0.98 | 513.4 | 32.8 | 73.2 | 52.51075 |
| Example 2 | 1 | 0.97 | 517.9 | 31.6 | 74 | 53.1172 |
| Example 3 | 1 | 0.96 | 519.5 | 31.3 | 73.1 | 51.29866 |
| Example 4 | 1 | 0.93 | 529.2 | 30.4 | 78.7 | 57.60132 |
| Example 5 | 1 | 0.92 | 537.6 | 30.5 | 80.2 | 59.17477 |
| Example 6 | 1 | 0.91 | 539.7 | 30 | 79.5 | 57.51428 |
| Example 7 | 1 | 0.91 | 544.5 | 29.6 | 74.8 | 50.91486 |
| Example 8 | 1 | 0.9 | 555.1 | 31.8 | 75 | 50.0625 |
| Example 9 | 1 | 0.93 | 529.1 | 31 | 90 | 75.33 |
| Example 10 | 1 | 0.93 | 529.5 | 31 | 93 | 80.4357 |
| Example 11 | 1 | 0.93 | 530 | 30 | 95 | 83.9325 |
| Example 12 | 1 | 0.93 | 530 | 30 | 99 | 91.1493 |
| Example 13 | 1 | 0.93 | 530 | 30 | 95 | 83.9325 |
| Example 14 | 1 | 0.92 | 535 | 30 | 98 | 88.3568 |
| Com. Exm. 1 | 1 | 0.93 | 530 | 31 | 48.2 | 21.60613 |
| Com. Exm. 2 | 1 | 0.93 | 530 | 30 | 46.2 | 19.85029 |

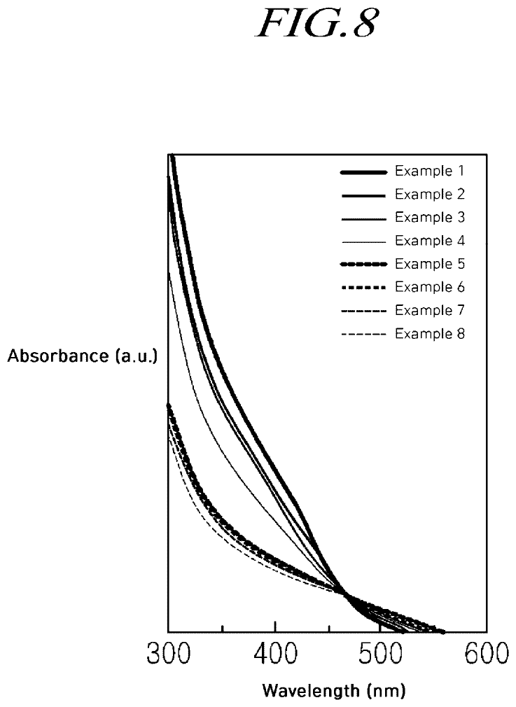

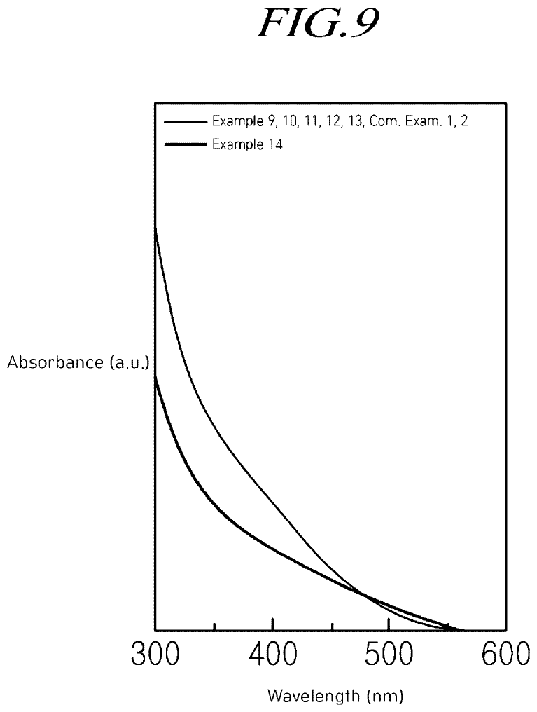

The above Examples 1 to 8 changed the reaction temperature in the process of Preparation Example 6, and the above Examples 9 to 14 and Comparative Examples 1 and 2 changed the contents of the silver precursor, the indium precursor, and the gallium precursor and the reaction temperature in the process of Preparation Example 6 to measure the integral value of the absorbance of the quantum dot in the range of 300 nm to 470 nm and the quantum yield (QY), and ultimately derived the effective absorption efficiency. FIG. 8 is a graph of an absorbance with respect to a wavelength of Examples 1 to 8. FIG. 9 is a graph a graph of an absorbance with respect to a wavelength of Examples 9 to 14 and Comparative Examples 1 to 2.

As described above, since the larger the band gap energy, the light in the short wavelength region is emitted and high energy is required, the absorption value in the entire range 300 nm to 800 nm is greater. The smaller the band gap energy, the light in the long wavelength region is emitted and the absorption value in the entire range is relatively smaller compared to the light emission in the short wavelength region.

In addition, the more light is emitted in the short wavelength range, the larger the integral value in the short wavelength range. The more light is emitted in the long wavelength range, the smaller the integral value in the short wavelength range.

For the display device, the blue wavelength for enabling the green quantum dot to emit light may be less than or equal to 470 nm. In this way, the overlap between the excitation wavelength and the emission wavelength required to enable luminescence can be avoided.

Since the absorbance in the short wavelength region differs depending on the emission wavelength, the effective absorption efficiency represents absorption according to quantum yield regardless of the emission wavelength by using the integral value of the absorbance from 300 nm to 470 nm when the integral value of the absorbance from 300 nm to 800 nm is 1.

Accordingly, the effective absorption efficiency quantifies the luminescence energy according to the degree of absorption of the quantum dot, and quantifies the value for the absorption rate compared to emission, rather than the emission compared to absorption. Accordingly, the quantum dot with a higher effective absorption efficiency is the quantum dot that absorbs better.

As can be seen from Table 1, and FIGS. 8 and 9, the quantum dots in Examples 1 to 14 each have the effective absorption efficiency of greater than or equal to 50%, and the quantum dots in Comparative Examples 1 to 2 each have the effective absorption efficiency of less than 50%,

In the examples, the band gap alignment occurs in the core 12 with a smaller band gap, the first shell 14 is a type 1 structure that does not affect light emission, and the second shell 16 is a type 2 structure that affects light emission, and the quantum dot has the quantum yield of greater than or equal to 70%, with good emission and absorption of light.

On the other hand, in the case of Comparative Example 1, the quantum confinement effect is smaller than the examples due to the single shell, showing lower luminescence efficiency and effective absorption efficiency. In the case of Comparative Example 2, although it is a multi-shell, it shows a significantly lower effective absorption efficiency compared to the examples at the same wavelength due to the reverse type band gap structure.

Through Examples 1 to 14 of AgInGaS/AgGaS/GaS quantum dots and Comparative Examples 1 and 2, it was described that AgInGaS/AgGaS/GaS quantum dots having an effective absorption efficiency of greater than or equal to 50% may improve luminescence efficiency.

In the above-described Examples 1 to 14, AgInGaS/AgGaS/GaS quantum dots in which the Group I element is Ag, the Group III element is Ga, and the Group VI element is S, used in the first shell and the second shell, are representatively described. However, AgInGaS/first shell/second shell quantum dots in which the Group I element included in the first shell is element other than Ag, the Group III element included in the first and second shells 14 and 16 is one of Al, In, and Tl other than Ga and the Group VI element included in the first and second shells 14 and 16 is one of Se and Te other than S, can also improve luminous efficiency for the same reason as described above.

In addition, AgInGaS/shell quantum dots without a second shell can also improve luminescence efficiency for the same reasons as described above.

The above description has been presented to enable any person skilled in the art to make and use the technical idea of the present invention, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present invention. The above description and the accompanying drawings provide an example of the technical idea of the present invention for illustrative purposes only. That is, the disclosed embodiments are intended to illustrate the scope of the technical idea of the present invention. Thus, the scope of the present invention is not limited to the embodiments shown, but is to be accorded the widest scope consistent with the claims. The scope of protection of the present invention should be construed based on the following claims, and all technical ideas within the scope of equivalents thereof should be construed as being included within the scope of the present invention.

### CROSS-REFERENCE TO RELATED APPLICATION

This application claims priority benefit from Korean Patent Application No. 10-2022-0154930, filed on Nov. 17, 2022, the entire contents of which are hereby expressly incorporated by reference for all purposes as if fully set forth herein.

1. A quantum dot comprising:
a core including silver (Ag), indium (In), gallium (Ga) and sulfur(S); and
a shell on the core,
wherein the quantum dot has an effective absorption efficiency defined by [Equation 1] of greater than or equal to 50%:
$$effective absorption efficiency ( \% ) = \frac{{Abs}_{300 nm ∼ 470 nm} \times {( QY )}^{2}}{10000} \times 100 \qquad [ Equation 1 ]$$
wherein Equation 1,
Abs_{300 nm˜470 nm} is an integral value of an absorbance of the quantum dot in the range of 300 nm to 470 nm when the integral value of the absorbance of the quantum dot in the range of 300 nm to 800 nm is 1, and QY is a quantum yield of the quantum dot.

2. The quantum dot of claim 1, wherein the quantum yield of the quantum dot is greater than or equal to 70% when the effective absorption efficiency of the quantum dot is greater than or equal to 50%.

3. The quantum dot of claim 1, wherein the shell includes at least one of a Group I element and a Group III element; and a Group VI element.

4. The quantum dot of claim 1, wherein a Group I element included in the shell includes one or more selected from Li, Na, K, Rb, Cs, Cu, Ag, and Au.

5. The quantum dot of claim 1, wherein a Group III element included in the shell includes one or more selected from Au. Al, Ga, In and Tl.

6. The quantum dot of claim 1, wherein a Group VI element included in the shell includes one or more selected from S, Se and Te.

7. The quantum dot of claim 1, wherein the shell including:
a first shell disposed on the core and including a Group I element and a Group III element, and a Group VI element; and
a second shell disposed on the first shell and including a Group III element and a Group VI element,
wherein the Group III element and the Group VI element included in the first shell and the second shell are the same or different.

8. A method for manufacturing a quantum dot, the method comprising:
a core preparation step of preparing a core by injecting and reacting a silver precursor, an indium precursor, a gallium precursor, a sulfur precursor and a solvent in a first reactor; and
a shell preparation step of preparing a shell by injecting and reacting the prepared core in a second reactor containing a precursor including specific elements,
wherein the quantum dot has an effective absorption efficiency defined by [Equation 1] of greater than or equal to 50%:
$$effective absorption efficiency ( \% ) = \frac{{Abs}_{300 nm ∼ 470 nm} \times {( QY )}^{2}}{10000} \times 100 \qquad [ Equation 1 ]$$
wherein Equation 1,
Abs_{300 nm˜470 nm} is an integral value of an absorbance of the quantum dot in the range of 300 nm to 470 nm when the integral value of the absorbance of the quantum dot in the range of 300 nm to 800 nm is 1, and QY is a quantum yield of the quantum dot.

9. The method of claim 8, wherein the quantum yield of the quantum dot is greater than or equal to 70% when the effective absorption efficiency of the quantum dot is greater than or equal to 50%.

10. The method of claim 8, wherein the specific elements include at least one of a Group I element and a Group III element; and a Group VI element.

11. The method of claim 8, wherein a Group I element included in the shell includes one or more selected from Li, Na, K, Rb, Cs, Cu, Ag, and Au.

12. The method of claim 8, wherein a Group III element included in the shell includes one or more selected from Au. Al, Ga, In and Tl.

13. The method of claim 8, wherein a Group VI element included in the shell includes one or more selected from S, Se and Te.

14. The method of claim 8, wherein the shell including:
a first shell disposed on the core and including a Group I element and a Group III element, and a Group VI element, and
a second shell disposed on the first shell and including a Group III element and a Group VI element,
wherein the Group III element and the Group VI element included in the first shell and the second shell are the same or different.

15. The method of claim 14, wherein the shell preparation step including:
a first shell preparation step of preparing the first shell by injecting and reacting the prepared core in the first reactor containing a Group I precursor including the Group I element and a Group III precursor including the Group III element, and a Group VI precursor including the Group VI element; and
a second shell preparation step of preparing the second shell by injecting and reacting the prepared core/first shell in the second reactor containing a Group III precursor including the Group III element and a Group VI precursor including the Group VI element.

16. An electronic device comprising:
a display device including a light emitting diode including a quantum dot; and
a controller driving the display device,
wherein the quantum dot comprising: a core including silver (Ag), indium (In), gallium (Ga) and sulfur(S), and a shell on the core, wherein the quantum dot has an effective absorption efficiency defined by [Equation 1] of greater than or equal to 50%:
$$effective absorption efficiency ( \% ) = \frac{{Abs}_{300 nm ∼ 470 nm} \times {( QY )}^{2}}{10000} \times 100 \qquad [ Equation 1 ]$$
wherein Equation 1,
Abs_{300 nm˜470 nm} is an integral value of an absorbance of the quantum dot in the range of 300 nm to 470 nm when the integral value of the absorbance of the quantum dot in the range of 300 nm to 800 nm is 1, and QY is a quantum yield of the quantum dot.

17. The electronic device of claim 16, wherein the quantum yield of the quantum dot is greater than or equal to 70% when the effective absorption efficiency of the quantum dot is greater than or equal to 50%.

18. The electronic device of claim 16, wherein the shell includes at least one of a Group I element and a Group III element; and a Group VI element.

19. The electronic device of claim 16, wherein the shell including:
a first shell disposed on the core and including a Group I element and a Group III element, and a Group VI element, and
a second shell disposed on the first shell and including a Group III element and a Group VI element,
wherein the Group III element and the Group VI element included in the first shell and the second shell are the same or different.
